(19) United States
(12) Patent Application Publication
(10) Pub. No.: US 2026/0136924 A1
(43) Pub. Date: May 14, 2026

(54) POWER MODULE WITH LOCAL HEAT SPREADER

(71) Applicant: Microchip Technology Incorporated, Chandler, AZ (US)

(72) Inventors: Shesh Mani Pandey, Gilbert, AZ (US); Zichen Zhang, Chandler, AZ (US)

(73) Assignee: Microchip Technology Incorporated, Chandler, AZ (US)

(21) Appl. No.: 19/061,592

(22) Filed: Feb. 24, 2025

Related U.S. Application Data
(60) Provisional application No. 63/720,526, filed on Nov. 14, 2024.

(51) Int. Cl. H01L 23/367; H01L 23/00; H01L 23/373; H01L 25/07

(52) U.S. Cl. CPC H10W 40/22; H10W 40/255; H10W 90/00; H10W 90/754

(57) ABSTRACT

A power module may include a plurality of dies and a heat spreader. The plurality of dies may include a first die subset and a second die subset. The first die subset may be associated with a power module hot spot, such that the first die subset may be associated with a higher operating temperature than the second die subset. The heat spreader may underlie each die of the first die subset. The heat spreader may be operable to reduce the operating temperature of the first die subset.

### CROSS-REFERENCE TO RELATED APPLICATIONS

The current patent application claims the benefit under 35 U.S.C. § 119(e) of the priority date of U.S. Provisional Application Ser. No. 63/720,526; titled “LOCAL HEAT SPREADER FOR POWER MODULES”; and filed Nov. 14, 2024. The Provisional Application is hereby incorporated by reference, in its entirety, into the current patent application.

### TECHNICAL FIELD

Various examples of the present disclosure relate to local heat spreaders for power modules.

### BACKGROUND

Power modules may have a non-uniform temperature distribution during operation. The non-uniform temperature distribution may lead to power module hot spots. Power module hot spots may be associated with dies of a power module operating at higher operating temperatures than other dies of the power module. The power module hot spots can cause performance issues and degradation of the power module due to the high operating temperatures.

This background discussion is intended to provide information related to the present invention which is not necessarily prior art.

### SUMMARY OF THE INVENTION

According to various examples of the present disclosure, a power module may include a plurality of dies and a heat spreader. The plurality of dies may include a first die subset and a second die subset. The first die subset may be associated with a power module hot spot, such that the first die subset may be associated with a higher operating temperature than the second die subset. The heat spreader may underlie each of the first die subset. The heat spreader may be operable to reduce the operating temperature of the first die subset.

According to various examples of the present disclosure, a power module may include a plurality of dies and a heat spreader. The plurality of dies may include a die subset that includes at least one but not all of the dies. The die subset may be associated with a power module hot spot, such that the die subset may be associated with a higher operating temperature than the dies not included in the die subset. The heat spreader may underlie each die of the die subset. The heat spreader may be operable to reduce the operating temperature of the die subset.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example power module;

FIG. 2 illustrates an example power sub-module including a local heat spreader;

FIGS. 3A-3D illustrate an example power sub-module including a local heat spreader at various stages of a manufacturing process; and

FIG. 4 illustrates an example power sub-module including local heat spreaders.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

Terms of relative location and direction (for example, above, below, left, right, upper, lower, vertical, lateral (or horizontal)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Various examples of the present disclosure relate to a power module including local heat spreaders. The local heat spreaders may be located at power module hot spots. The local heat spreaders may be configured to reduce a local temperature of the power module hot spots to maintain a temperature distribution of the power module within a threshold range during operation.

In various examples, the power module may include a set of sub-modules. Each sub-module may include a plurality of dies. The hot spots may be located at one more of the dies of one or more of the sub-modules. The local heat spreaders may underly the die(s) associated with the hot spots.

The power module may be utilized in high voltage applications (e.g., >1.2 kV) and may be incorporated into a variety of different uses, such as automotive systems, deep well drilling, aircraft systems, railway systems, transportation systems, micro-electromechanical systems (MEMS), energy transmission systems, consumer devices, medical imaging devices, mass spectrometry devices, particle accelerators, data center systems, server systems, computing systems, and industrial systems, without limitation. In various examples, the power module may be utilized as a power switch, buck converter, boost converter, buck-boost converter, DC/DC converter, rectifier, inverter, flyback converter, AC/DC converter, and DC/AC converter, and the like, without limitation. In various examples, the power module may be configured to operate at high operating temperatures (e.g., >150° C.). It would be appreciated by one of ordinary skill in the art that the power modules described herein may be utilized in lower voltage applications (e.g., <1.2 kV) and/or at lower operating temperatures (e.g., <150° C.) without departing from the spirit of the present disclosure.

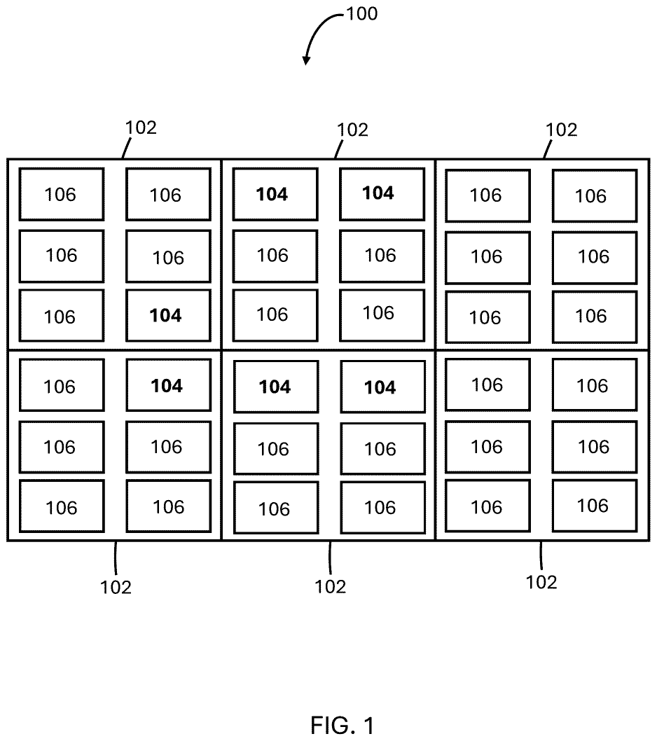

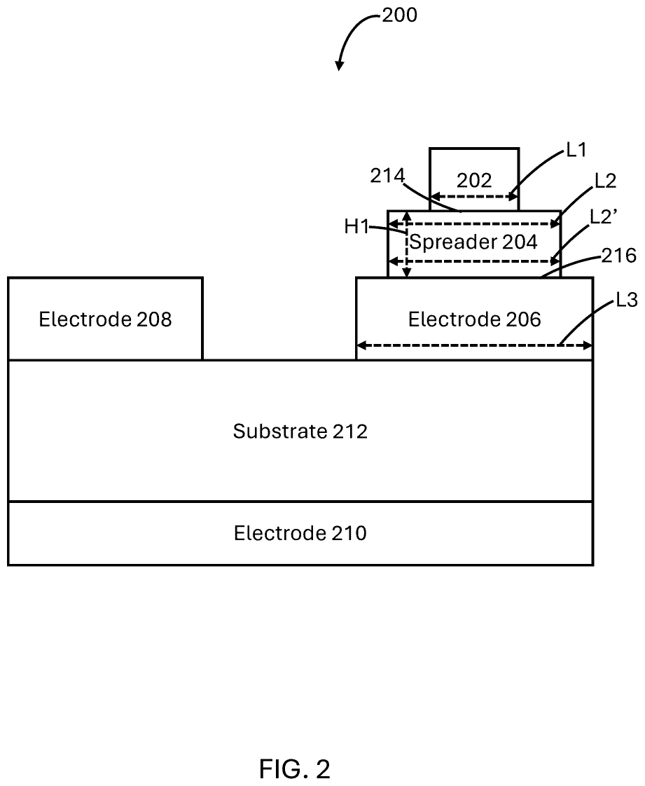

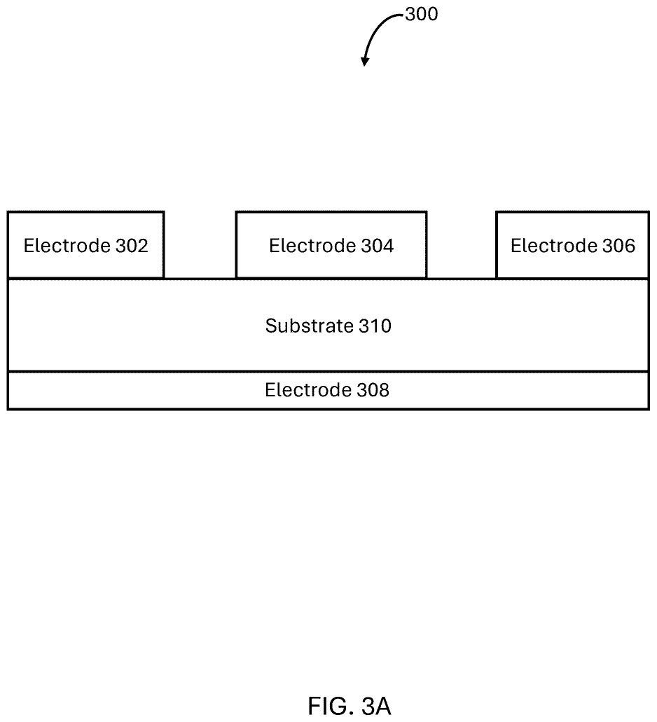

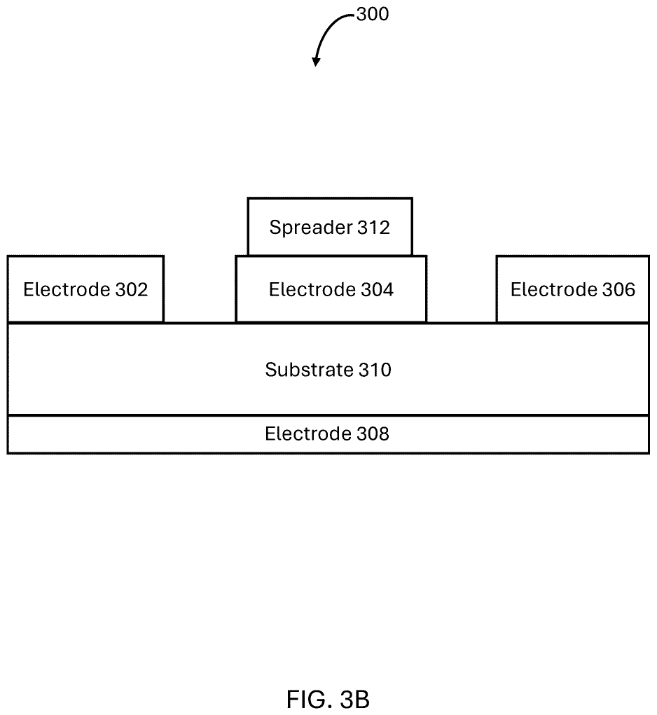

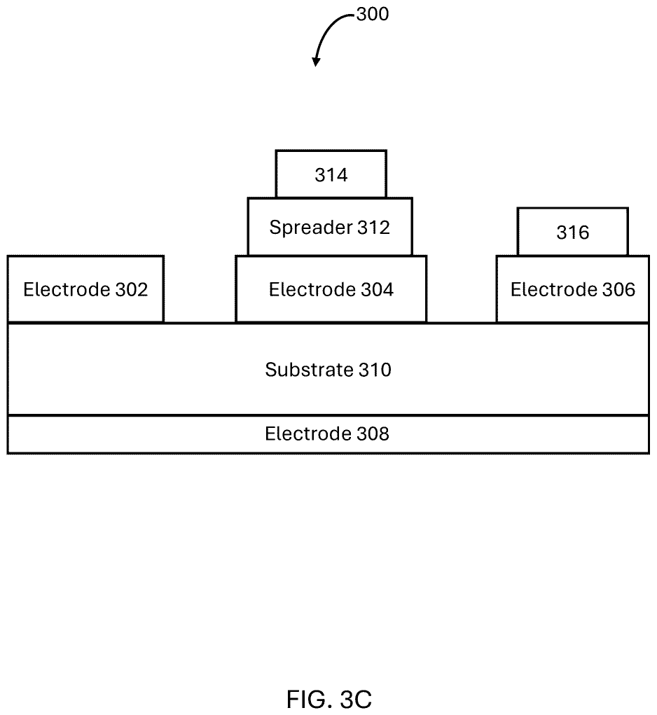

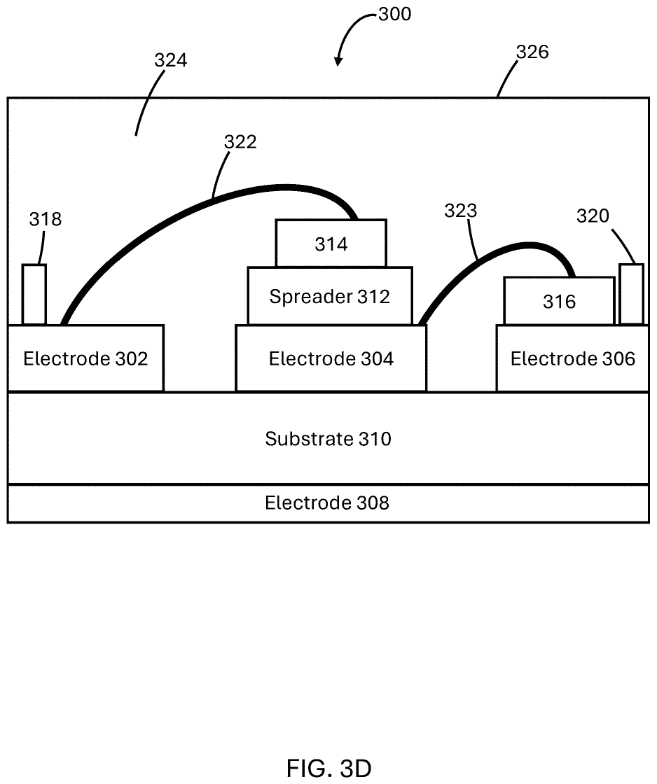

FIG. 1 illustrates a power module 100 including sub-modules 102. The sub-modules 102 may cooperatively include a first subset of dies 104 and a second subset of dies 106. (It will be appreciated that each sub-module 102 may include a combination of dies from the first and second subsets. Alternatively, one or more of the sub-modules 102 may include dies from only one of the subsets.) The dies 104 and the dies 106 may include insulated-gate bipolar transistor (IGBT) chips, silicon carbide (SiC) chips, and diode chips, without limitation. Each sub-module 102 may include a combination of different chips. For example, each sub-module may include four (4) IGBT chips and two (2) diode chips. In another example, each sub-module may include four (4) SiC chips and two (2) diode chips. Each of the dies 104, 106 may be mounted on an electrode (e.g., the electrode 206 of FIG. 2 and/or the electrodes 304, 306 of FIGS. 3A-3D).

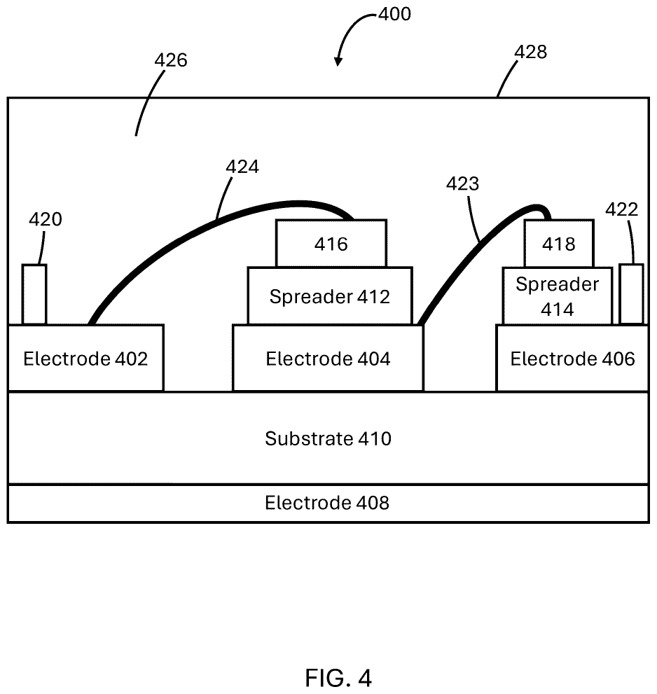

In various examples, heat spreaders (e.g., the heat spreader 204 of FIG. 2, the heat spreader 312 of FIGS. 3B-3D, and/or the heat spreader 412, 418 of FIG. 4) may be interposed between the dies 104 and their corresponding electrodes. The heat spreaders may be configured to dissipate heat generated during operation of the power module 100. During operation, the heat spreaders may maintain the operating temperatures of the power module hot spots within a threshold range of the operating temperatures of the other locations of the power module 100. The threshold range may be 10° C. or less, without limitation. For example, if the dies 106 operate at a temperature of 150° .C, the heat spreader may reduce a temperature of the dies 104 to around 160° C. or less. Accordingly, local heat spreaders underlying the dies 104 may prevent overheating of the power module 100 and may extend a lifetime of the power module 100 by avoiding destructive effects of overheating while being less costly, less bulky, and using less material compared to applying global heat spreaders. The heat spreaders are described in more detail with reference to FIG. 2, FIGS. 3B-3D, and FIG. 4.

FIG. 2 illustrates a diagram of a sub-module 200. The sub-module 200 may correspond to one of the sub-modules 102 described with reference to FIG. 1. The sub-module 200 may include a die 202, a heat spreader 204, an electrode 206, an electrode 208, an electrode 210, and a substrate 212. The die 202 may correspond to one of the dies 104 described with reference to FIG. 1. The die 202 may be located on a hot spot of the sub-module 200.

The heat spreader 204 may be mounted on the electrode 206 and may underly the die 202. The heat spreader 204 and the die 202 may cooperatively define a die/spreader interface 214. The heat spreader 204 and the electrode 206 may cooperatively define a spreader/electrode interface 216. The heat spreader 204 may dissipate heat generated by the die 202 during operation of the power sub-module 200 in a direction towards the substrate 212 or generally away from the die 202.

In various examples, a first spreader length L2, second spreader length L2′ and a spreader height H1 of the heat spreader 204 may be dependent on a die length L1 of the die 202, an electrode length L3 of the electrode 206, and a heat dissipation angle θ of the heat spreader 204. The die length L1 may extend along the die/spreader interface 214. The heat spreader length L2 may extend along the die/spreader interface 214 and the second heat spreader length L2′ may extend along the electrode/spreader interface 216. The first and second heat spreader lengths L2, L2′ may be about equal. However, according to some aspects of the present disclosure, the lengths L2 and L2′ may be dissimilar. For example, in some applications, it may be desirable for the length L2′ (along the spreader/electrode interface) to be greater than the length L2 (along the die/spreader interface), such that the spreader tapers upwardly. The electrode length L3 may extend along the spreader/electrode interface 216. A ratio between the die length L1, the spreader lengths L2, L2′ and the electrode length L3 may be determined based on a height H1 of the heat spreader 204 and the heat dissipation angle θ of the heat spreader 204. For example, the ratio may be determined based on the following formulas: L3>L2>(L1+2*H1)*tan(θ) and L3>L2′>(L1+2*H1)*tan(θ). In various examples, the die 202 may be substantially centered on the heat spreader 204.

In various examples, the heat spreader 204 may include an isotropic material, such as carbon-based materials, graphite, graphene, and/or diamond, without limitation. The isotropic material may dissipate heat generally evenly in all directions, providing a uniform heat transfer from the die 202 towards the substrate 212. Accordingly, the isotropic material may dissipate heat at an angle greater than forty five (45) degrees from the die 202 towards the substrate 212.

In an alternative example, the heat spreader may include an anisotropic material, such as copper, carbon, graphene, or a composite of materials including copper, carbon, and/or graphene, without limitation. The anisotropic material may dissipate heat from the die 202 toward the substrate 212 at about a forty five (45) degree angle. Some anisotropic materials may provide a heat dissipation angle θ of less than forty five (45) degrees or greater than forty five (45) degrees depending on a structure of the composite anisotropic materials. For example, layers of graphene may be implemented at a particular angle to provide a desired heat dissipation angle θ.

In various examples, the electrodes 206, 208, and 210 may be copper (Cu) based electrodes. The electrodes 206, 208, 210 may be operable to conduct electrical energy. In various examples, the substrate 212 may be a ceramic based substrate. More specifically, the substrate 212 may be include insulating materials such as alumina (Al2O3), aluminum nitride (AlN), silicon nitride (SiN), or beryllium oxide (BeO), and the like, without limitation. The substrate 212 may provide thermal and/or electrical insulation to the power sub-module 200. In various examples, the electrodes 206, 208, 210 and the substrate 212 may collectively be a direct bonded copper (DBC) substrate.

FIG. 3A illustrates a power sub-module 300 in an initial manufacturing stage. The power module 300 may correspond to one of, or a portion of one of, the sub-modules 102 described with reference to FIG. 1. The power sub-module 300 may include electrodes 302, 304, 306, 308, and a substrate 308. The power sub-module 300 may be formed from a DBC substrate. A typical DBC substrate may include copper plates (e.g., the electrodes 302, 304, 306, 308) bonded to a ceramic substrate (e.g., the substrate 310). The electrode 304 may be located at a power module hot spot. The substrate may be a ceramic based substrate including one or more of the insulating materials described with reference to the substrate 212 of FIG. 2.

FIG. 3B illustrates the power sub-module 300 having a heat spreader 312 mounted on the electrode 304. The heat spreader 312 may include any of the same materials, dimensions, and heat dissipation properties described with reference to the heat spreader 204 of FIG. 2. In various examples, the heat spreader 312 may be mounted to the electrode 304 by means of soldering, bonding, adhesion, and the like, without limitation.

FIG. 3C illustrates the power sub-module 300 having a die 314 placed on the heat spreader 304 and a die 316 placed on the electrode 306. The die 314 may be substantially centered on the heat spreader 312. The die 314 may correspond to one of the dies 104 described with reference to FIG. 1. The die 316 may correspond to one of the dies 106 described with reference to FIG. 1. The dies 314, 316 may include any of the chips described with reference to the dies 104, 106 of FIG. 1. The die 314 may be mounted to the heat spreader 304 and the die 316 may be mounted to the electrode 306 by any die attachment means known to one of ordinary skill in the art, such as soldering, bonding, adhesion, and the like, without limitation.

FIG. 3D illustrates the power sub-module 300 in a final manufacturing stage. In the final manufacturing stage, the sub-module 300 may include leads 318, 320, bond wires 322, 323, an encapsulation 324, and a housing 326. The leads 318, 320 may provide an electrical connection to another device, such as a power input device, a power output device, and/or another sub-module 300, without limitation. The bond wire 322 may provide an electrical connection between the electrode 302 and the die 314. The bond wire 323 may provide an electrical connection between the electrode 304 and the die 316. Alternatively, the bond wire 323 may be connected directly (i.e., having a direct physical connection to the die 314) between the die 314 and the die 316 without departing from the spirit of the present disclosure.

The encapsulation 324 may provide thermal and electrical protection to the various components of the sub-module 300. The encapsulation 324 may be include materials having high dielectric strength, such as silicone gel (e.g., SiC), epoxy, and/or polyimide (PI), without limitation. Epoxy and/or PI based encapsulation materials may have a higher dielectric strength than silicone gel encapsulation materials. Accordingly, epoxy and/or PI based encapsulations may be utilized to shield the various components of the sub-module from high temperatures and/or high electrical field intensity conditions. For example, an electric field of the sub-module 300 may have a higher intensity at respective intersections of one of the electrodes 302, 304, 306, 310, the substrate 308, and the encapsulation 324. An intersection of an electrode, a substrate, and an encapsulation may be referred to as a triple point.

FIG. 4 illustrates a power-sub module 400. The power-sub module 400 may include electrodes 402, 404, 406, 408, a substrate 410, heat spreaders 412, 414, dies 416, 418, leads 420, 422, bond wires 423, 424, an encapsulation 426, and a housing 428. The components of power sub-module 400 (e.g., the electrodes 402, 404, 406, 408, substrate 410, heat spreader 412, dies 416, 418, leads 420, 422, and so on) may be the same as the power sub-module 300 described with reference to FIGS. 3A-3D, except for the addition of the heat spreader 414. The heat spreaders 412, 414 may include any of the same materials, dimensions, and heat dissipation properties described with reference to the heat spreader 204 of FIG. 2. The dies 416, 418 may correspond to the dies 104 described with reference to FIG. 1. Accordingly, the dies 416, 418 may be located at power module hot spots. The dies 416, 418 may include any of the chips described with reference to the dies 104, 106 of FIG. 1. The die 416 may be mounted to the heat spreader 412 and the die 418 may be mounted to the heat spreader 414 by any die attachment means known to one of ordinary skill in the art, such as soldering, bonding, adhesion, and the like, without limitation.

According to various examples of the present disclosure, a power module may include a plurality of dies and a heat spreader. The plurality of dies may include a first die subset and a second die subset. The first die subset may be associated with a power module hot spot, such that the first die subset may be associated with a higher operating temperature than the second die subset. The heat spreader may underlie each die of the first die subset. The heat spreader may be operable to reduce the operating temperature of the first die subset.

According to various examples of the present disclosure, a power module may include a plurality of dies and a heat spreader. The plurality of dies may include a die subset that includes at least one but not all of the dies. The die subset may be associated with a power module hot spot, such that the die subset may be associated with a higher operating temperature than the dies not included in the die subset. The heat spreader may underlie each die of the die subset. The heat spreader may be operable to reduce the operating temperature of the die subset.

In combination with any of the previous examples, a heat spreader may be operable to reduce an operating temperature of a first die subset to within a range of a second die subset.

In combination with any of the previous examples, a heat spreader may include an anisotropic material.

In combination with any of the previous examples, an anisotropic material may include copper.

In combination with any of the previous examples, a heat spreader may include an isotropic material.

In combination with any of the previous examples, an isotropic material may include carbon-based material.

In combination with any of the previous examples, a first die subset may include multiple dies each associated with a respective heat spreader.

In combination with any of the previous examples, each die of a first die subset may cooperate with a respective heat spreader to define a die/spreader interface. Each die of the first die subset may present a die length extending along the die/spreader interface. The respective heat spreader may present a first heat spreader length extending along the die/spreader interface. The first heat spreader length may be greater than the die length.

In combination with any of the previous examples, a power module may include a plurality of electrodes. Each die of a first die subset may be associated with a respective one of the electrodes. The respective heat spreader may be interposed between the die of the first die subset and the respective one of the electrodes.

In combination with any of the previous examples, a respective heat spreader and a respective electrode may cooperatively define a spreader/electrode interface. The respective heat spreader may present a second heat spreader length extending along the spreader/electrode interface. The respective electrode may cooperatively define an electrode length extending along the spreader/electrode interface.

In combination with any of the previous examples, first and second heat spreader lengths may be about equal.

In combination with any of the previous examples, a second heat spreader length may be less than an electrode length.

In combination with any of the previous examples, a ratio between a die length and a first spreader length may be determined based on a heath of a heat spreader and a heat dissipation angle of the heat spreader.

In combination with any of the previous examples, a heat dissipation angle may be about forty-five (45) degrees.

In combination with any of the previous examples, a heat dissipation angle may be greater than forty-five (45) degrees.

In combination with any of the previous examples, each die of a first die subset may be substantially centered on a respective heat spreader.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A power module comprising:
a plurality of dies including a first die subset and a second die subset, said first die subset being associated with a power module hot spot, such that the first die subset is associated with a higher operating temperature than the second die subset; and
a heat spreader underlying each die of the first die subset, said heat spreader being operable to reduce the operating temperature of the first die subset.

2. The power module of claim 1,
said heat spreaders being operable to reduce the operating temperatures of the first die subset to within a threshold range of the second die subset.

3. The power module of claim 1,
said heat spreader including an anisotropic material.

4. The power module of claim 3,
said anisotropic material including copper.

5. The power module of claim 1,
said heat spreader including an isotropic material.

6. The power module of claim 5,
said isotropic material including a carbon-based material.

7. The power module of claim 1,
said first die subset including multiple dies each associated with a respective heat spreader.

8. The power module of claim 7,
each die of the first die subset cooperating with said respective heat spreader to define a die/spreader interface,
each die of the first die subset presenting a die length extending along the die/spreader interface,
said respective heat spreader presenting a first heat spreader length extending along the die/spreader interface,
said first heat spreader length being greater than the die length.

9. The power module of claim 8, further including:
a plurality of electrodes,
each die of the first die subset being associated with a respective one of the electrodes, with said respective heat spreader being interposed between the die of the first die subset and the respective one of the electrodes.

10. The power module of claim 9,
said respective heat spreader and said respective one of the electrodes cooperatively defining a spreader/electrode interface,
said respective heat spreader presenting a second heat spreader length extending along the spreader/electrode interface,
said respective one of the electrodes cooperatively defining an electrode length extending along the spreader/electrode interface.

11. The power module of claim 10,
said first and second heat spreader lengths being about equal.

12. The power module of claim 10,
said second heat spreader length being less that then electrode length.

13. The power module of claim 8,
a ratio between the die length and the first spreader length being determined based on a height of the heat spreader and a heat dissipation angle of the heat spreader.

14. The power module of claim 13,
said heat dissipation angle being about forty five (45) degrees.

15. The power module of claim 13,
said heat dissipation angle being greater than forty five (45) degrees.

16. The power module of claim 8,
each die of the first die subset being substantially centered on the respective heat spreader.

17. A power module comprising:
a plurality of dies including a die subset that comprises at least one but not all of the dies, said die subset being associated with a power module hot spot, such that the die subset is associated with a higher operating temperature than the dies not included in the die subset; and
a heat spreader underlying each die of the die subset, said heat spreader being operable to reduce the operating temperature of the die subset.

18. The power module of claim 17,
said heat spreaders being operable to reduce the operating temperatures of the die subset to within a threshold range of the dies not included in the die subset.

19. The power module of claim 17,
said die subset including multiple dies each associated with a respective heat spreader.

20. The power module of claim 19,
each die of the die subset cooperating with said respective heat spreader to define a die/spreader interface,
each die of the die subset presenting a die length extending along the die/spreader interface,
said respective heat spreader presenting a first heat spreader length extending along the die/spreader interface,
said first heat spreader length being greater than the die length,
a ratio between the die length and the first spreader length being determined based on a height of the heat spreader and a heat dissipation angle of the heat spreader.
